(19) United States
(12) Patent Application Publication
(10) Pub. No.: US 2015/0228445 A1
(43) Pub. Date: Aug. 13, 2015

(54) METHOD AND APPARATUS FOR THREE DIMENSIONAL ION IMPLANTATION

(71) Applicant: Varian Semiconductor Equipment Associates, Inc., Gloucester, MA (US)

(72) Inventor: Shengwu Chang, South Hamilton, MA (US)

(73) Assignee: Varian Semiconductor Equipment Associates, Inc., Gloucester, MA (US)

(21) Appl. No.: 14/179,988

(22) Filed: Feb. 13, 2014

(51) Int. Cl. H01J 37/147; H01J 37/317; H01J 37/30

(52) U.S. Cl. CPC H01J 37/1474; H01J 37/3007; H01J 37/3171; H01J 2237/15; H01J 2237/31701; H01J 2237/30483

(57) ABSTRACT

A scan system for processing a substrate with an ion beam may include a scanner to receive the ion beam having a shape of a ribbon beam, the ribbon beam having a beam width along a first axis and beam height along a second axis that is perpendicular to the first axis, the beam width being at least three times greater than the beam height; and a scan power supply to send signals to the scanner to generate a deflecting field that deflects the ribbon beam along the second axis.

### FIELD

The present embodiments relate to substrate processing, and more particularly, to ion implantation of substrates.

### BACKGROUND

Conventional apparatus used to treat substrates with ions include beamline ion implanters and plasma immersion ion implantation tools. In beamline ion implanters ions are extracted from a source, mass analyzed and then transported to the substrate surface. Ion implantation has particularly been used for several decades to introduce dopants into semiconductor wafers during manufacturing of devices such as logic devices and memory devices. Such devices have been based upon planar transistor technology in which dopant regions are commonly formed as layers that lie parallel to the surface of the semiconductor wafer being implanted. Implantation is often performed by directing a beam of parallel ions to the substrate surface at an implant angle and ion energy determined by device requirements, such as a desired implant depth for dopants being implanted. In many systems a narrow ribbon beam or scanned spot beam that treats a substrate area of similar shape and size as a ribbon beam is provided to the substrate.

Such conventional implantation apparatus are adequate to introduce dopants into substrates in which planar semiconductor devices are to be formed. However, as device dimension scales to smaller sizes, three dimensional (3D) devices such as fin field effect transistors (finFETs) are increasingly used in the manufacturing of semiconductor devices such as logic devices. Such three dimensional devices include transistors in which source/drain regions and channel regions of a transistor are formed in semiconductor structures that extend vertically from a horizontal wafer surface. Conventional ion implantation apparatus such as that described above may not be ideally suited for controlling placement of dopant species within such 3D structures.

It is with respect to these and other considerations that the present improvements have been needed.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment, a scan system for processing a substrate with an ion beam may include a scanner to receive the ion beam in the shape of a ribbon beam, the ribbon beam having a beam width along a first axis and beam height along a second axis that is perpendicular to the first axis, the beam width being at least three times greater than the beam height. The scan system may further include a scan power supply to send signals to the scanner to generate a deflecting field that deflects the ribbon beam along the second axis.

In a further embodiment, an ion implanter for implanting a substrate may include an ion source to generate an ion beam and beamline components to shape the ion beam into a ribbon beam, the ribbon beam having a beam width along a first axis and beam height along a second axis that is perpendicular to the beam width, the beam width being at least three times greater than the beam height. The ion implanter may also include a scan system to transmit the ribbon beam and to apply a deflecting field to the ribbon beam along the second axis, wherein the ribbon beam impacts the substrate over an ion angular distribution about a third axis perpendicular to a substrate plane defined by the substrate.

In a further embodiment, a method to process a substrate using an ion beam may include shaping the ion beam into a ribbon beam having a beam width along a first axis and beam height along a second axis perpendicular to the first axis, the beam width being at least three times greater than the beam height; directing the ribbon beam to pass through a scanner; and applying a deflecting field to the ribbon beam along the second axis when the ribbon beam passes through the scanner.

### BRIEF DESCRIPTION OF THE DRAWINGS

FIG. 1A depicts an isometric composite view of a scan system;

FIG. 1B depicts a side view of the scan system of FIG. 1A in accordance with embodiments of the disclosure;

FIG. 2A depicts an ion implanter consistent with embodiments of the disclosure;

FIG. 2B depicts another ion implanter consistent with additional embodiments of the disclosure;

FIGS. 3A and 3B exhibit a pair of exemplary waveforms that may be produced by a scan system;

FIGS. 3C and 3D show an additional pair of exemplary waveforms that may be produced by a scan system;

FIG. 4 depicts an exemplary ion angular distribution;

FIG. 5 depicts another exemplary ion angular distribution;

FIG. 6 illustrates a scenario of ion implantation of a substrate using the ion angular distribution of FIG. 4;

FIG. 7 illustrates a scenario of ion implantation of a substrate using the ion angular distribution of FIG. 5;

FIGS. 8A and 8B illustrate a pair of exemplary waveforms;

FIG. 8C illustrates another exemplary ion angular distribution;

FIG. 9 illustrates a scenario of ion implantation of a substrate using the ion angular distribution of FIG. 8C;

FIGS. 10A and 10B show an additional pair of exemplary waveforms that may be produced by a scan system;

FIGS. 10C and 10D show a further pair of exemplary waveforms that may be produced by a scan system;

FIG. 10E illustrates further exemplary ion angular distributions; and

FIG. 11 depicts an isometric composite view of another scan system according to further embodiments.

### DETAILED DESCRIPTION

The embodiments described herein provide apparatus and methods for controlling angular incidence of ions directed to a substrate. In particular, the present embodiments provide a novel scan system and methods to manipulate ribbon ion beams (“ribbon beams”) that may impact a substrate over an ion angular distribution rather than at a uniform angle of incidence as in conventional ribbon beam processing. The term “ion angular distribution” (IAD) may refer to the mean angle of incidence of ions in an ion beam with respect to a reference direction or reference axis such as a perpendicular to a substrate, as well as to the width of distribution or range of angles of incidence centered around the mean angle, and the shape of the ion angular distribution. In the embodiments disclosed herein the novel scan system may be employed in an ion implanter that includes at least one beamline component to generate a fixed ribbon beam or a scanned spot beam that is scanned over time over an area that has the shape of a ribbon beam cross-section. Either of these ion beams may be referred to herein as a “ribbon beam.”

As detailed below, a scan system of the present embodiments includes a scanner to receive the ion beam in the shape of a ribbon beam, where the ribbon beam has a beam width along a first axis and beam height along a second axis that is perpendicular to the first axis. The beam width of the ribbon beam as received by the scanner may be greater than the width of the substrate. The scan system may also include a scan power supply to send signals to the scanner to generate a deflecting field that deflects the ribbon beam along the second axis. In this manner the scanner may deflect the ribbon beam through a range of angles about a third axis that is perpendicular to the first axis and perpendicular to the second axis. For example, the ribbon beam may propagate as a beam of parallel ions along the third axis as it enters the scanner, and is subject to the deflecting field, which may be variable in intensity. As detailed below, this may cause the ribbon beam to be deflected over time over an ion angular distribution about the third axis and to also impact the substrate over the ion angular distribution about the third axis.

In various embodiments, as further discussed with respect to the figures to follow, a scanner may include a first scan plate and a second scan plate disposed between the at least one beamline component that generates the ribbon beam and a substrate stage that supports the substrate. In this manner, the ribbon beam is transmitted between the first scan plate and second scan plate before striking the substrate. In some embodiments, the scan power supply includes a first power supply to apply a first waveform to the first scan plate and a second power supply to apply a second waveform to the second scan plate, wherein the first and second waveform generate the deflecting field as an oscillating deflecting field. The oscillating deflecting field causes the ribbon beam to be deflected (scanned) back and forth parallel to the second axis, creating an ion angular distribution about the third axis as the ribbon beam propagates towards the substrate. In some embodiments, the back and forth scanning of the ribbon beam may take place at an oscillation frequency greater than 100 Hz, so that the scanned ribbon beam appears to the substrate as an envelope that contains ions over the ion angular distribution defined by the scanning. In particular embodiments, the scan system may be deployed in ion implanters in which a substrate stage is configured to scan the substrate back and forth parallel to the second axis at a frequency less than 2 Hz. Accordingly, the scanned ribbon beam, whose scan period may be on the order of microseconds or milliseconds, may appear to the scanning substrate as a quasi-stationary envelope of ions that appears to be continuously incident on the substrate over the ion angular distribution.

In further embodiments, the scan power supply may be configured to output a signal to adjust scanning of the ribbon beam. For example, the scan power supply may output a signal to adjust a first amplitude of the first waveform, a second amplitude of the second waveform, or both. In this manner, the ion angular distribution of the ribbon beam may be adjusted as desired.

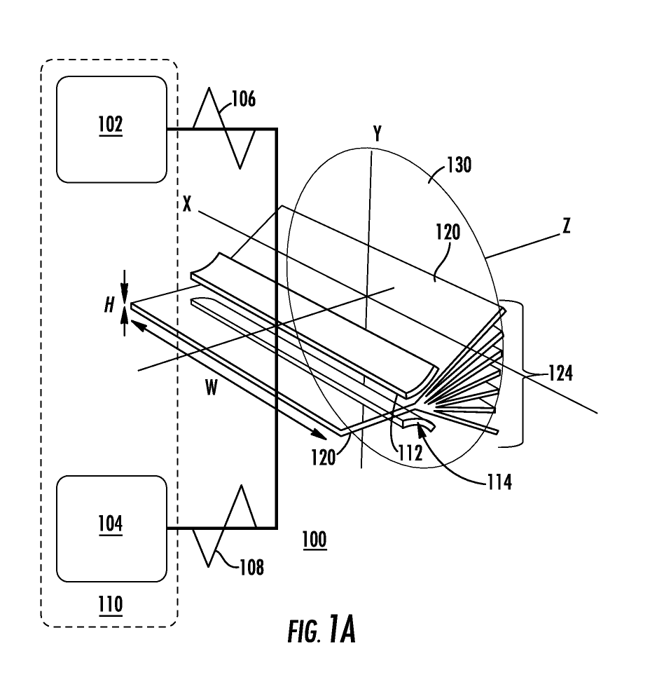

FIG. 1A depicts an isometric composite view of a scan system 100, while FIG. 1B depicts a side view of the scan system 100 in accordance with embodiments of the disclosure. The scan system 100 includes a first scan plate, scan plate 112 and second scan plate, scan plate 114, which are configured to receive a ribbon beam 120. As illustrated in FIG. 1A and FIG. 1B, the ribbon beam 120 has a beam width W and beam height H that define a cross-section in an elongated ribbon shape in the X-Y plane of the Cartesian coordinate system illustrated. In various embodiments the ribbon beam 120 may have a beam width W that is at least three times greater than the beam height H. In some embodiments the ribbon beam 120 may have a beam width W that is greater than the width of the substrate along the X-axis. The beam width W may be tailored according to a substrate 130 to be treated by the ribbon beam 120. For example, in some embodiments the beam width W may be greater than 300 mm so as to cover a respective 300 mm diameter wafer. In some embodiments the beam height H may be 2 mm to 20 mm. However, the embodiments are not limited in this context.

As shown in FIG. 1A the scan system 100 further includes a scan power supply 110. In some embodiments a scan power supply may include the power supply 102, which is coupled to the scan plate 112, and a separate power supply, the power supply 104, which is coupled to the scan plate 114. The power supply 102 may output a voltage in the form of a waveform 106 to the scan plate 112, while the power supply 104 outputs a voltage in the form of a waveform 108 to the scan plate 114. As discussed below, the waveforms that are output to a pair of scan plates may be synchronized to produce a deflecting filed that changes with time as desired, such as an oscillating deflecting field. In some embodiments, an additional component (not shown) of the scan power supply 110, such as a controller may send signals to the power supply 102 and power supply 104 to synchronize waveforms output by the power supply 102 and power supply 104.

The synchronized waveforms, such as waveforms 106, 108 may generate an oscillating voltage difference between scan plate 112 and scan plate 114 that in turn generates an oscillating electric field that deflects the ribbon beam 120 when the ribbon beam 120 passes between the scan plate 112 and the scan plate 114. As shown in FIG. 1A, the ribbon beam enters a scanner (not separately shown) made up of the scan plate 112 and scan plate 114 while traveling along a direction parallel to the Z-axis, which is defined as the direction of propagation of an ion beam. The oscillating electric field may be aligned parallel to the Y-axis, that is, perpendicularly to the Z-axis and also perpendicularly to the X-axis, which itself is oriented parallel to the beam width W. Accordingly, such an oscillating electric field may not affect the beam width W, but rather may deflect the ribbon beam 120 over time over a range of angles of incidence about the Z-axis, producing the ion beam envelope 124. As suggested in FIGS. 1A and 1B, the ion beam envelope 124 represents the sum over time of the different positions of the ribbon beam 120 as it exits between the scan plate 112 and scan plate 114 while being subject to a deflecting field that oscillates parallel to the Y-axis.

In FIG. 1B seven different ribbon beams, ribbon beam 124a, ribbon beam 124b, ribbon beam 124c, ribbon beam 124d, ribbon beam 124e, ribbon beam 124f, and ribbon beam 124g are illustrated. Each ribbon beam 124a-124g represents the deflected ribbon beam 120 at a different point in time, and each forms a different angle of incidence with respect to a perpendicular 126 to a substrate plane 136 of the substrate 130, where the perpendicular 126 lies parallel to the Z-axis. In some examples, as detailed below, a frequency of an oscillating electric field generated between scan plates may be hundreds or thousands Hertz, such that adjacent ribbon beams, for example, ribbon beam 124a and ribbon beam 124b, may represent the deflected ribbon beam 120 at two successive intervals that are spaced apart by a few microseconds. As further shown in FIG. 1B, the substrate 130 may be disposed in a processing system such as an ion implanter that includes a substrate stage 132 configured to scan along the direction 134, which is parallel to the Y-axis. In some cases the substrate 130 may be scanned back and forth parallel to the Y-axis at a scan rate of 0.5 Hz. Accordingly, within one period of scanning the substrate 130, the ribbon beam 120 may be deflected back and forth parallel to the Y-axis many hundreds of times or thousands of times. In this manner, scanned ribbon beam 120 may appear to the substrate 130 and any features disposed on the surface of the substrate 130, not as discrete ribbon beams, but as the ion beam envelope 124 that is characterized by an ion angular distribution about the Z-axis.

As detailed in the FIGS. to follow, a scan system and in particular, a scan power supply, such as scan power supply 110, may be employed to adjust ion aspects of an ion angular distribution of a scanned ribbon beam provided to a substrate. For example, the scan power supply may also generate a signal to adjust a first amplitude of a waveform, such as the waveform 106, a second amplitude of a second waveform, such as the waveform 108, or both. This may be used to control the range of the angles of incidence of the ion beam envelope 124, where angle of incidence is designated by a. In the example of FIG. 1B the ribbon beams 124a-124g define a range of angles of incidence with respect to the Z-axis. This range of angles of incidence may equal 2αₘₐₓ, that is, +/−αₘₐₓ, with respect to the Z-axis, where αₘₐₓ is the angle formed by the deflected ion beam at the maximum deflection, such as that formed by ribbon beam 124a. In this example, the Z-axis lies parallel to the perpendicular 126 to the substrate plane 136, so that the ribbon beams 124a-124g from the same range of angles of incidence +/−αₐₘₐₓ with respect to the perpendicular 126.

In additional embodiments, a scan system, and in particular, a scan power supply, such as scan power supply 110, may be is configured to output a signal to adjust a first shape of the first waveform, such as waveform 106, a second shape of the second waveform, such as waveform 108, or both. This may be used to control other aspects of ion angular distribution of a scanned ribbon beam, such as whether or not the distribution of angles of incidence is a monomodal distribution (single peak), as discussed below.

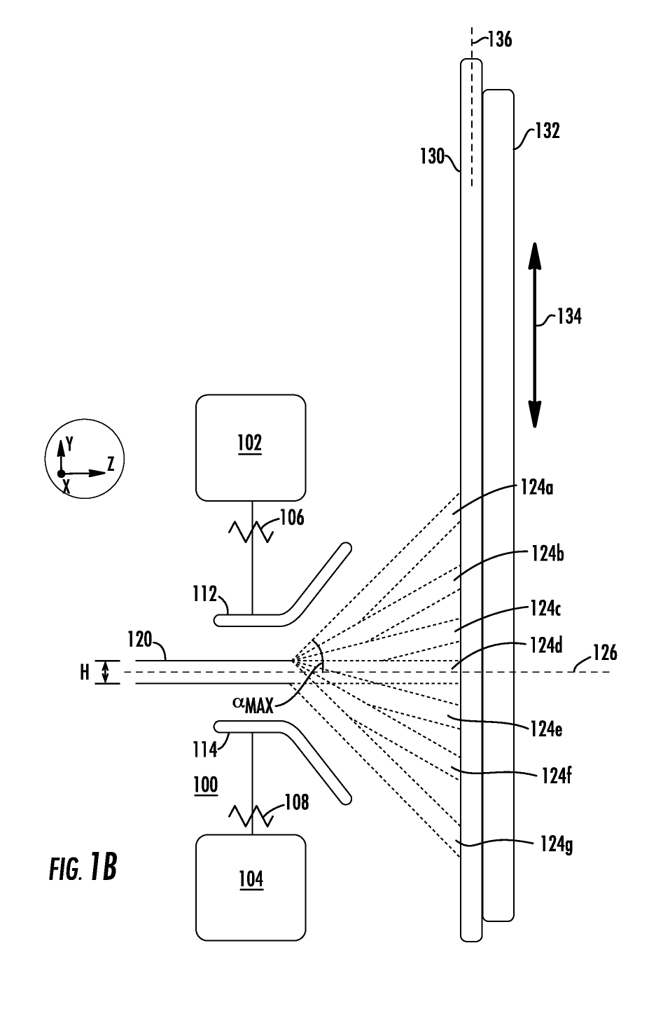

FIG. 2A and FIG. 2B depict alternative embodiments of ion implanters consistent with embodiments of the disclosure. In FIG. 2A an ion implanter 200 includes an ion source 202 that generates the ion beam 230. The ion implanter 200 is a beamline ion implanter, which may include various conventional components in which at least one beamline component is used to shape the ion beam 230 as a ribbon beam. In some embodiments, the ion source 202 may generate a diverging ion beam that passes through an analyzing magnet 204 and mass resolving slit 206, and emerges from the mass resolving slit 206 as a diverging ribbon beam. This diverging ribbon beam is collimated by the collimator 208 and may be decelerated through a deceleration lens 210 before passing between the scan plate 112 and scan plate 114. The power supply 102 and power supply 104 may provide voltage to the scan plate 112 and scan plate 114, respectively, as described above in order to generate a deflecting field that deflects the ribbon beam in a direction parallel to the Y-axis of the Cartesian coordinate system shown. It is to be noted that the absolute direction of X-axis and Z-axis as used herein may vary at different locations along the beamline, where the Z-axis may lie parallel to the central ray trajectory of an ion beam at any given location. In the example of FIG. 2A, the operation of beamline components such as ion source 202, analyzing magnet 204, mass resolving slit 206, collimator 208, and deceleration lens 210 may be performed as in conventional ion implanters, and are not discussed further herein.

The ion implanter 200 of FIG. 2A includes beamline components that generate the ion beam 230 as a fixed ribbon beam, that is, the ion beam has a ribbon beam shape instantaneously at any point in time. However, in other embodiments, an ion implanter may generate a spot ion beam whose cross section is less elongated than a ribbon beam. Such an ion implanter may include an additional scanner, a spot beam scanner, that is arranged according to conventional techniques to scan the spot beam along a fourth axis perpendicular to the Y-axis to generate a ribbon beam shape similar to that depicted for ion beam 230 as it enters the collimator 208. FIG. 2B depicts an ion implanter 250 that generates a spot beam 254 with use of the ion source 252. The ion implanter 250 also includes a spot beam scanner 256 that generates a scanned spot beam 258, which is received by a scanner comprising the scan plate 112 and scan plate 114. In either case of FIG. 2A or FIG. 2B, whether a ribbon beam is a fixed ribbon beam or formed from a scanned spot beam, the scan plate 112 and scan plate 114 may scan the given ribbon beam as described above with respect to FIGS. 1A and 1B.

It is to be noted that in various embodiments in which a ribbon beam is produced by scanning a spot beam, the frequency of scanning of the ribbon beam scanning may be adjusted according to the frequency of scanning of the spot beam that is used to create the ribbon beam. For example, referring to FIG. 1A and FIG. 2B, in some embodiments, a spot beam scanner positioned upstream of the collimator 208 may be employed to scan a spot beam back and forth in a direction parallel to the X-axis, as shown. After the scanned spot beam 258 is collimated and guided through the collimator 208 the scanned spot beam results in a ribbon beam whose width (longer dimension) extends along the X-axis and height extends parallel to the Y-axis, as shown in FIG. 1A. A first frequency employed by the first scanner, that is, spot beam scanner 256, may be 50 times or more greater than a second frequency used to scan the ribbon beam in a second scanner that is located downstream to the first scanner, such as the scanner represented by the scan plate 112 and scan plate 114, where the ribbon beam is scanned back and forth parallel to the Y-axis. In other embodiments, the second frequency employed by the second scanner to scan a ribbon beam may be 50 times or more greater than the first frequency used to scan the spot beam. In either set of embodiments, the first frequency used to scan the spot beam may be 50 times or more greater than a third frequency used to scan a substrate stage and substrate that is exposed to the scanned ribbon beam, such as substrate 130, where the substrate stage 132 and substrate 130 are scanned back and forth parallel to the Y-axis. In one particular embodiment, the frequency of substrate scanning is 2 Hz; the frequency of ribbon beam scanning is 100 Hz; and the frequency of spot beam scanning is 5000 Hz. In an additional embodiment, the frequency of substrate scanning is 2 Hz; the frequency of ribbon beam scanning is 5000 Hz; and the frequency of spot beam scanning is 100 Hz.

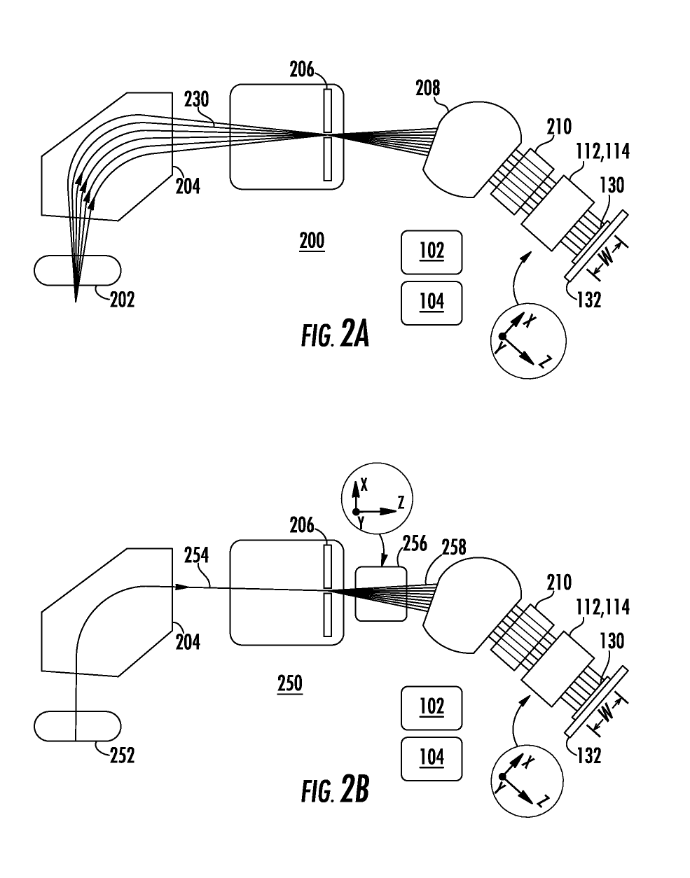

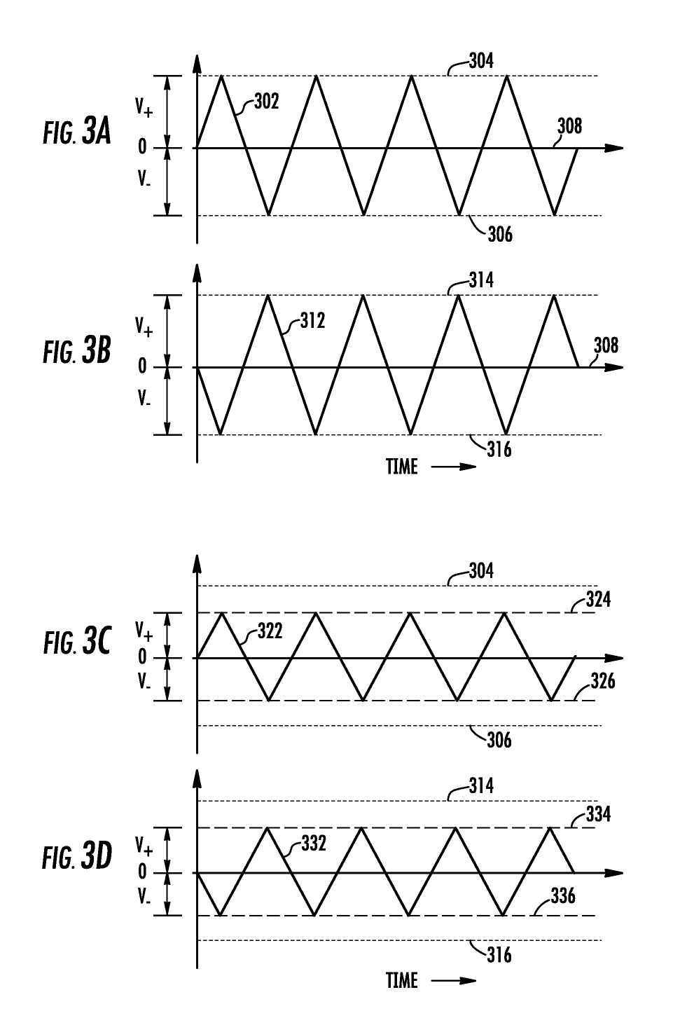

As noted above, in order generate a desired ion angular distribution for ions that impinge on a substrate the scan system of the present embodiments may generate a set of oscillating voltage signals as waveforms. These waveforms are applied to opposing scan plates of a scanner in order to scan a ribbon beam passing through the scanner, as illustrated below in FIGS. 3A-3D. Referring now to FIGS. 3A and 3B there are shown exemplary waveforms, waveform 302 and waveform 312, respectively. In one example, these waveforms may be generated by the power supply 102 and power supply 104, respectively, and may be applied to scan plate 112 and scan plate 114, respectively. Turning to FIG. 3A the waveform 302 may oscillate about zero voltage level 308 as shown, where V+ indicates positive voltage and V− indicates negative voltage. In some examples the maximum amplitude 304 of positive voltage of the waveform 302 may equal to the maximum amplitude 306 of the negative voltage. Turning to FIG. 3B the waveform 312 may also oscillate about zero voltage level 308 as shown. In some examples the waveform 302 may have a first period and the waveform 312 may have a second period that is equal to the first period. In some embodiments the maximum amplitude 314 of positive voltage of the waveform 312 may also be equal to the maximum amplitude 316 of negative voltage. As further shown in FIGS. 3A and 3B, the waveform 312 may exhibit a phase lag (or, equivalently, a phase lead) of 180 degrees with respect to the waveform 302. Referring also to FIG. 1A, when waveform 302 and waveform 312 are applied to scan plate 112 and scan plate 114, respectively, the direction of an electric field, which is determined by the difference between the waveform 312 and waveform 302, may oscillate back and forth parallel to the Y-axis. In particular embodiments the absolute value of the maximum amplitudes may be the same for maximum amplitude 304, maximum amplitude 306, maximum amplitude 314, and maximum amplitude 316. In this manner, a ribbon beam, such as ribbon beam 120, may be deflected symmetrically over an ion angular distribution about the Z-axis.

Turning now to FIGS. 3C and 3D there are shown additional exemplary waveforms, waveform 322 and waveform 332, respectively. In one example, these waveforms may be generated by the power supply 102 and power supply 104, respectively, and may be applied to scan plate 112 and scan plate 114, respectively. In some embodiments the maximum amplitude 324 of positive voltage of the waveform 322 may also be equal to the maximum amplitude 326 of negative voltage. In some examples the waveform 322 may have a first period and the waveform 332 may have a second period that is equal to the first period. As further shown in FIGS. 3C and 3D, the waveform 322 may exhibit a phase lag (or, equivalently, a phase lead) of 180 degrees with respect to the waveform 332, which may result in the generation of an electric field that oscillates back and forth parallel to the Y-axis (see FIG. 1A). In particular embodiments the absolute value of the maximum amplitudes may be the same for maximum amplitude 324, maximum amplitude 336, maximum amplitude 334, and maximum amplitude 336. In this manner, a ribbon beam, such as ribbon beam 120, may also be deflected symmetrically over an ion angular distribution about the Z-axis.

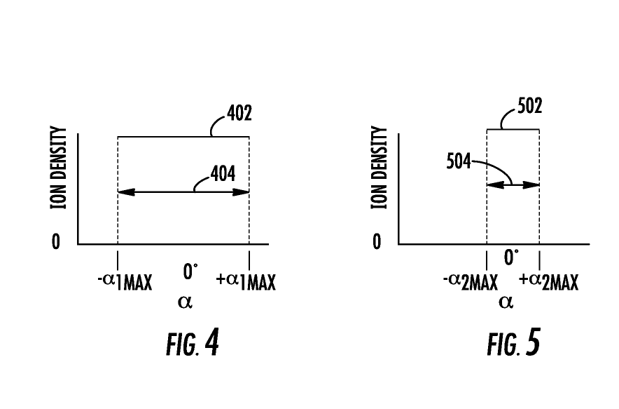

A difference between the pairs of waveforms, waveform 322 and waveform 332, and their respective counterparts, waveform 302 and waveform 312, is that the absolute value of maximum amplitudes are lesser in waveforms 322 and waveform 332. In this manner, the maximum electric field strength generated when the scan plate 112 and scan plate 114 receive the waveform 322 and waveform 332, respectively, is less than that generated when the scan plate 112 and scan plate 114 receive the waveform 302 and waveform 312, respectively. Thus, in a scenario in which the waveform 322 and waveform 332 are applied to a pair of scan plates, the range of angles of incidence of a deflected ribbon beam about the Z-axis is less than that generated by application of the combination of waveform 302 and waveform 312. FIG. 4 depicts a curve having a peak shape that represents an exemplary ion angular distribution (IAD) 402, which may result from the application of waveform 302 and waveform 312. FIG. 5 depicts an exemplary ion angular distribution (IAD) 502, which may result from the application of waveform 322 and waveform 332. The IAD 402 and IAD 502 represent the relative number of ions or ion density in a scanned ribbon beam as a function of the angle of incidence is designated by a, where a may be defined with respect to the initial direction of a ribbon beam before entering a scanner, as shown in FIG. 1B. In the case where the substrate plane 136 is aligned perpendicularly to the initial direction (parallel to the Z-axis) of a ribbon beam, the perpendicular 126 to the substrate plane 136 is also aligned along the initial direction of the ribbon beam.

In this case, the IAD 402 and IAD 502 may also denote the distribution of ion angles of a scanned ribbon beam with respect to a perpendicular to a substrate. The IAD 402 is characterized by a pair of maximum angles, shown as +/−α₁ₘₐₓ with respect to a mean, shown as “0” and the IAD 502 is characterized by a pair of maximum angles, shown as +/−₂ₘₐₓ with respect to its mean, also shown as “0.” The ion angular range shown for In the example shown for both IAD 402 and IAD 502, the ion density may be uniform between −α₁ₘₐₓ and +α₁ₘₐₓ or between −α₂ₘₐₓ and +α₂ₘₐₓ, respectively. The ion density falls to zero at values above the maximum angles indicated. The width 404 of the IAD 402 is simply +α₁ₘₐₓ-α₁ₘₐₓ and the width 504 of the IAD 502 is simply +α₁ₘₐₓ-α₁ₘₐₓ. Each of the parameters of width and maximum angle are greater in the IAD 402 in comparison to IAD 502. Thus, a scan system of the present embodiments may modify the IAD of a scanned ribbon beam by adjusting of amplitude of waveforms, which may change parameters including the width of the ion angular distribution.

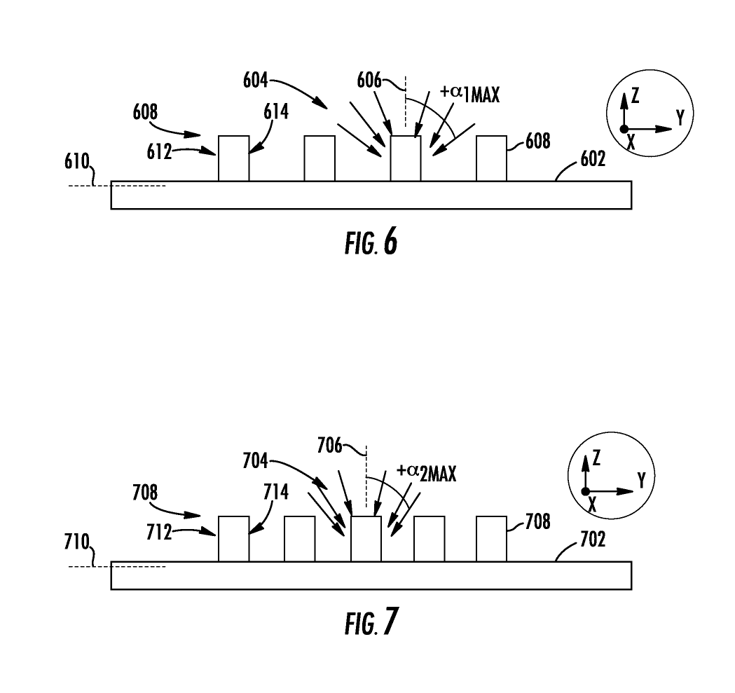

The adjusting of IAD of a scanned ribbon beam as shown in FIGS. 4 and 5 may be useful for tailoring the treatment of a substrate, including substrates that have 3D features which are to be implanted at least in part at a non-zero angle with respect to perpendicular. FIG. 6 and FIG. 7 illustrate two different scenarios of ion implantation in which a scanned ribbon beam is used to treat a substrate using the IAD 402 and IAD 502, respectively. In FIG. 6, the ions 604, which represent ions from a scanned ribbon beam exhibiting the IAD 402, are directed to a substrate 602. The ions 604 form a range of angles of incidence with respect to a perpendicular 606 to a plane 610 of the substrate 602. The substrate 602 includes features 608, which extend vertically from the surface of the substrate 602 parallel to the Z-axis. Each feature 608 has a sidewall 612 and sidewall 614 as illustrated. In one example the features 608 may be fins to form finFET devices. It may be desirable to implant the fins at an angle α, with respect to the perpendicular 606. Depending upon the height of the features 608 along the Z-axis and their spacing, it may be appropriate to treat the features 608 with ions having the IAD 402, which is exhibited by ions 604. For example, the features 608 may be spaced apart from one another such that at least a portion of the sidewall 612 and sidewall 614 may be treated by the ions 604, particularly those whose trajectories form a larger angle α, with respect to the perpendicular 606.

In FIG. 7, the ions 704, which represent ions from a scanned ribbon beam exhibiting the IAD 502, are directed to a substrate 702. The ions 704 form a range of angles of incidence with respect to a perpendicular 706 to a plane 710 of the substrate 702. As shown in FIG. 7. The substrate 702 includes features 708, where each feature 708 has a sidewall 712 and sidewall 714 as illustrated. It may be desirable to implant the fins at an angle α, with respect to the perpendicular 706. Depending upon the height of the features 708 along the Z-axis and their spacing, it may be appropriate to treat the features 708 with ions having the IAD 502, which is exhibited by ions 704. For example, the features 708 may have the same height but may be spaced closer to one another than features 608. For this reason the maximum value of α that can effectively treat a desired portion of a sidewall 712 or sidewall 714 of a given feature 708 without striking an a feature 708 that is adjacent the given feature may be less than in the example of features 608. For this reason the IAD 502 exhibited by ions 704 may be more appropriate for implanting into features 708, since +/−α₂ₘₐₓ is less than +/−α_{1max.} and ions are therefore less likely to be screened by adjacent features, such as features 708, from implanting into the intended portions of a sidewall of a feature 708.

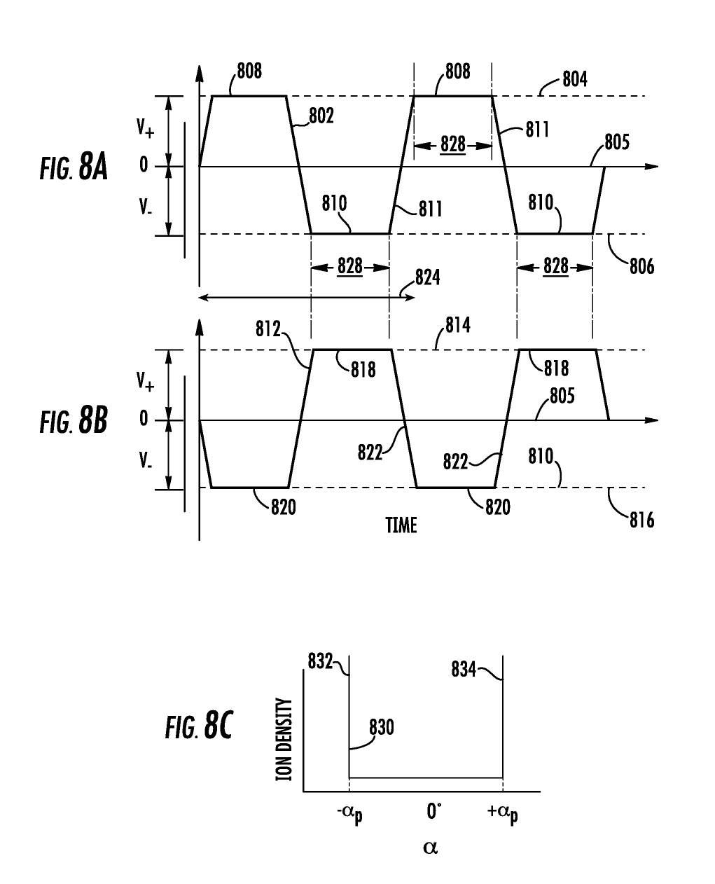

In addition to adjusting the range of angles of incidence of ions in a scanned ribbon beam, the scan systems of the present embodiment may adjust the shape of an IAD. Referring now to FIGS. 8A and 8B there are shown exemplary waveforms, waveform 802 and waveform 812, respectively. In one example, these waveforms may be generated by the power supply 102 and power supply 104, respectively, and may be applied to scan plate 112 and scan plate 114, respectively. Turning to FIG. 8A the waveform 802 may oscillate about zero voltage level 805 as shown, where V+ indicates positive voltage and V− indicates negative voltage. In some examples the maximum amplitude 804 of positive voltage of the waveform 802 may equal to the maximum amplitude 806 of the negative voltage. Turning to FIG. 8B the waveform 812 may also oscillate about zero voltage level 808 as shown. In some examples the waveform 802 may have a first period and the waveform 812 may have a second period that is equal to the first period. In some embodiments the maximum amplitude 814 of positive voltage of the waveform 812 may also be equal to the maximum amplitude 816 of negative voltage. As further shown in FIGS. 8A and 8B, the waveform 812 may exhibit a phase lag (or, equivalently, a phase lead) of 180 degrees with respect to the waveform 802.

In contrast to the triangular shape of waveform 302 and waveform 312, both waveform 802 and waveform 812 have a more complex shape. In particular within any given period corresponding to period 824 of the waveform 802, the waveform 802 exhibits a first plateau represented by portion 808 in which the voltage is maintained at the maximum amplitude 804 of positive voltage. The waveform 802 also exhibits a second plateau represented by portion 810 in which the voltage is maintained at the maximum amplitude 806 of negative voltage. Another characteristic of the waveform 802 is that the portion 808 and portion 810 also extend over the majority of a given period 824. The transition portions 811, during which the voltage swings between negative and positive, occupy less time. Similarly during a given period 824 of the waveform 812, the waveform 812 exhibits a first plateau represented by portion 818 in which the voltage is maintained at the maximum amplitude 814 of positive voltage and a second plateau represented by portion 820 in which the voltage is maintained at the maximum amplitude 816 of negative voltage. Additionally, portion 818 and portion 820 also extend over the majority of a given period 824, while transition portions 822 in which voltage swings between negative and positive, occupy less time.

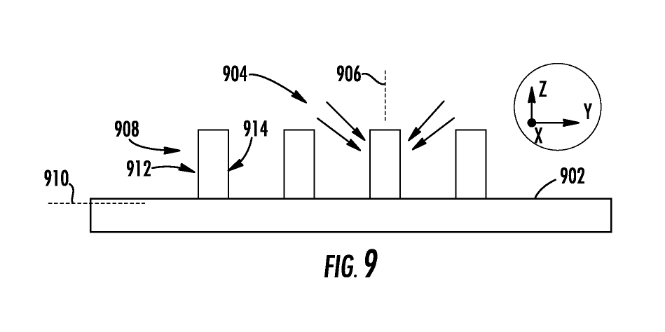

When the waveform 802 and waveform 812 are applied to scan plate 112 and scan plate 114, respectively, an oscillating electric filed may be generated in which the electric field rapidly swings between a maximum positive or negative value, while the electric field is maintained at the maximum positive of maximum negative value for extended portions of a period 824, which are shown as the intervals 828. This has the effect of deflecting a scanned ribbon beam in a manner that creates an IAD having a bimodal distribution. FIG. 8C illustrates one such ion angular distribution, the IAD 830, which includes a peak 832 and a peak 834. In some examples, the peak 832 may correspond to an angle −αₚ while the peak 834 corresponds to an angle +αₚ. Such a distribution of angles of incidence of ions in a scanned ribbon beam may be appropriate to treat substrates having three dimensional devices in which implantation into sidewalls of device structures that extend vertically is to be emphasized over implantation into horizontal surfaces. FIG. 9 illustrates a scenarios of ion implantation in which a scanned ribbon beam is used to treat a substrate using the IAD 830. In FIG. 9, the ions 904 are directed to a substrate 902, forming a bimodal distribution of angles of incidence with respect to a perpendicular 906 to a plane 910 of the substrate 902. As shown in FIG. 9, the substrate 902 includes features 908, which extend vertically from the surface of the substrate 902 parallel to the Z-axis. Each feature 908 has a sidewall 912 and sidewall 914 as illustrated. It may be desirable to implant the fins at an angle +/−αₚ with respect to the perpendicular 906. Accordingly, the IAD 830 exhibited by ions 904 may be particularly suited to simultaneously implanting the sidewall 912 and sidewall 914 while the substrate 902 is scanned along the Y-axis. At the same time, due to the bimodal nature of the IAD 830 fewer ions may be incident on the features 908 along the Z-axis.

It is to be noted that the aforementioned waveforms provided by the disclosed embodiments are merely exemplary. Other shapes are possible including sinusoidal shapes or complex waveform shapes. Because the IAD of a scanned beam is determined by waveforms generated from a scan power supply, the IAD can be altered as rapidly as the time needed to generate a signal to alter the waveform.

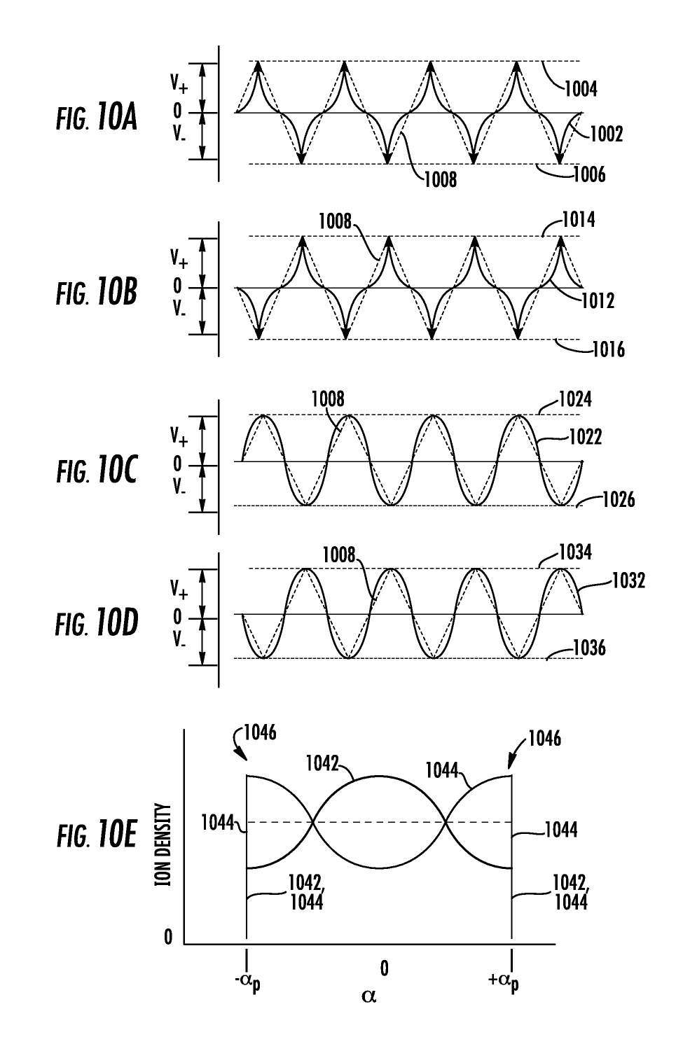

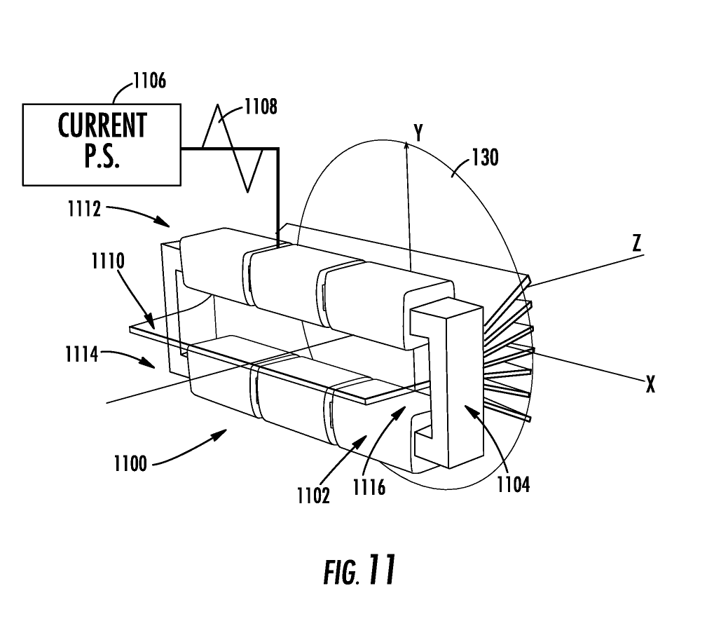

FIGS. 10A and 10B show an additional pair of exemplary waveforms that may be produced by a scan system. In FIG. 10A the waveform 1002 may be a spiked waveform as shown that oscillates between a maximum amplitude 1004 of positive voltage and a maximum amplitude 1006 of negative voltage. In FIG. 10B the waveform 1012 may be a spiked waveform that oscillates between a maximum amplitude 1014 of positive voltage and a maximum amplitude 1016 of negative voltage. The waveform 1012 may exhibit a phase lag of one hundred eighty degrees with respect to the waveform 1012. Simultaneous application of the waveform 1012 by scan plate 112 and the waveform 1002 may result in the generation of a less abrupt ion angular distribution as compared to IAD 402 and IAD 502. Also shown in FIGS. 10A and 10B for reference is an exemplary triangular waveform 1008, which may generate an IAD similar to that of FIG. 4 or FIG. 5. FIG. 10E depicts an exemplary IAD. IAD 1042, which may be generated by application of the waveform 1002 and waveform 1012. The IAD 1042 is characterized by a pair of maximum angles, shown as +/−α₃ₘₐₓ. The ion intensity is greatest zero degrees and has a varying ion intensity at angles between the pair of maximum angles. In this case, the ion intensity varies gradually and has a minimum intensity at the maximum angles.

FIGS. 10C and 10D show a further pair of exemplary waveforms that may be produced by a scan system. In FIG. 10C the waveform 1022 may be a sinusoidal waveform that oscillates between a maximum amplitude 1024 of positive voltage and a maximum amplitude 1026 of negative voltage. In FIG. 10D the waveform 1032 may be a sinusoidal waveform that oscillates between a maximum amplitude 1034 of positive voltage and a maximum amplitude 1036 of negative voltage. The waveform 1032 may exhibit a phase lag of one hundred eighty degrees with respect to the waveform 1022. Simultaneous application of the waveform 1032 by scan plate 112 and the waveform 1022 may result in the generation of a less abrupt ion angular distribution as compared to IAD 402 and IAD 502. FIG. 10E also depicts an exemplary IAD, shown as IAD 1044. which may be generated by application of the waveform 1022 and waveform 1032. The IAD 1044 is characterized by a pair of maximum angles, shown as +/−α_{3max.} The IAD 1044 is characterized by two separate peaks shown as peaks 1046, in which ion intensity is greatest at the maximum angles and has a varying ion intensity at angles between the pair of maximum angles. In this case, the ion intensity varies gradually and has a minimum intensity at zero degrees. In further embodiments, other ion distributions are possible.

Thus, the various embodiments of FIGS. 10A-10E illustrate that by varying the slope of the scan wave form, the ion angular distribution can be adjusted, so that instead of a uniform angular distribution that results from a linear sloped scan waveform, the waveform can be tailored to emphasize desired angles of incidence. Referring also to FIG. 6, a benefit of adjusting the ion angular distribution is to be able to implant the substrate 602 with a desired dose rate for each different location of a 3D device structure, such as sidewall 612 and 614.

In further embodiments, static voltages may be applied to a pair of scan plates in order to deflect a ribbon beam at a fixed angle of incidence with respect to a substrate plane. Accordingly, the scan systems of the present embodiments provide flexibility in tailoring the angles of incidence of a scanned ribbon beam for treating a substrate, including real-time changes of IAD of a scanned ribbon beam.

Moreover, in further embodiments, in conjunction with scanning a ribbon beam about the Z-axis, a substrate stage such as substrate stage 132 may be rotated about the Z-axis or tilted about the Y-axis to provide further flexibility in treating three dimensional structures. The embodiments are not limited in this context.

In additional embodiments of the disclosure, scanning of a ribbon beam may be performed by a magnetic scanner. FIG. 11 depicts an embodiment of a scan system that includes a magnetic scanner 1100 that is configured to scan a ribbon beam 1110 over a range of angles of incidence similarly to the embodiment of FIG. 1A. In this example electromagnetic coils are provided to scan the ribbon beam 1110 back and forth by generating an oscillating magnetic field that causes the ribbon beam 1110 to be deflected along a direction parallel to the Y-axis. The magnetic scanner 1100 includes a metal portion, which may be a steel bar in the shape of a loop. The metal portion is surrounded by at least one coil in the upper region 1112 of the magnetic scanner and at least one coil in the lower region 1114 of the scanner, such that the coils define a gap to transmit the ribbon beam 1110. In one embodiment as illustrated in FIG. 11, the coils 1102 are configured as a set of three coils in the upper region 1112 and three coils in the lower region 1114.

A current power supply 1106 is configured to output an oscillating current 1108 that is applied to the coils 1102. All the coils 1102 may be connected in a manner that current flows through the coils 1102 in the same direction so as to produce a magnetic field that is aligned along the X-axis inside the gap 1116. The coils 1102 in the upper region 1112 may have a same size as the coils 1102 in the lower region 1114, or may be identical in the number of turns within a coil in order to generate a magnetic field that is uniform along the X-axis.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A scan system for processing a substrate with an ion beam, comprising:
a scanner to receive the ion beam having a shape of a ribbon beam, the ribbon beam having a beam width along a first axis and beam height along a second axis that is perpendicular to the first axis, the beam width being at least three times greater than the beam height; and
a scan power supply to send signals to the scanner to generate a deflecting field that deflects the ribbon beam along the second axis.

2. The scan system of claim 1, wherein the scanner deflects the ribbon beam through a range of angles about a third axis that is perpendicular to a substrate plane defined by the substrate, wherein the ribbon beam impacts the substrate over an ion angular distribution about the third axis.

3. The scan system of claim 1, wherein the scanner comprises a first scan plate and a second scan plate, wherein the ribbon beam is transmitted between the first scan plate and second scan plate.

4. The scan system of claim 3, wherein the scan power supply comprises a first power supply to apply a first waveform to the first scan plate and a second power supply to apply a second waveform to the second scan plate, wherein the first and second waveform generate the deflecting field as an oscillating deflecting field.

5. The scan system of claim 4, wherein the scan power supply is configured to output a signal to adjust at least one of: a first amplitude of the first waveform and a second amplitude of the second waveform.

6. The scan system of claim 4, wherein the second waveform has a phase lag of 180 degrees with respect to the first waveform.

7. The scan system of claim 2, wherein the range of angles is +/−45 degrees about the third axis.

8. The scan system of claim 2, wherein the ion angular distribution has two separate peaks.

9. The scan system of claim 1, wherein the scanner is configured to generate the deflecting field as an oscillating deflecting field having an oscillation frequency greater than 100 Hz.

10. An ion implanter for implanting a substrate, comprising:
an ion source to generate an ion beam;
at least one beamline component to shape the ion beam into a ribbon beam, the ribbon beam having a beam width along a first axis and beam height along a second axis that is perpendicular to the beam width, the beam width being at least three times greater than the beam height; and
a scan system to transmit the ribbon beam and to apply a deflecting field to the ribbon beam along the second axis, wherein the ribbon beam impacts the substrate over an ion angular distribution about a third axis perpendicular to a substrate plane defined by the substrate.

11. The ion implanter of claim 10, wherein the scan system comprises:
a first scan plate and a second scan plate disposed between the at least one beamline component and a substrate stage that supports the substrate, wherein the ribbon beam is transmitted between the first scan plate and second scan plate; and
a first power supply to apply a first waveform to the first scan plate and a second power supply
to apply a second waveform to the second scan plate.

12. The ion implanter of claim 11, wherein the scan system is configured to output a signal to adjust at least one of: a first amplitude of the first waveform and a second amplitude of the second waveform.

13. The ion implanter of claim 11, wherein the scan system is configured to output a signal to adjust a first shape of the first waveform, a second shape of the second waveform, or both.

14. The ion implanter of claim 10, further comprising a substrate stage configured to scan the substrate parallel to the second axis.

15. The ion implanter of claim 14, wherein the scan system is configured to generate the deflecting field as an oscillating deflecting field having an oscillation frequency greater than 100 Hz, and wherein the substrate stage is configured to scan the substrate back and forth parallel to the second axis at a frequency less than 2 Hz.

16. The ion implanter of claim 10, wherein the at least one beamline component comprises a spot beam scanner configured to receive a spot ion beam and generate the ribbon beam by scanning the spot beam along a third axis that is perpendicular to the second axis.

17. The ion implanter of claim 10, wherein the scan system comprises a magnetic scanner.

18. A method to process a substrate using an ion beam, comprising:
shaping the ion beam into a ribbon beam having a beam width along a first axis and beam height along a second axis perpendicular to the first axis, the beam width being at least three times greater than the beam height;
directing the ribbon beam to pass through a scanner; and
applying a deflecting field to the ribbon beam along the second axis when the ribbon beam passes through the scanner.

19. The method of claim 18, further comprising applying the deflecting field to deflect the ribbon beam through a range of angles about a third axis that is perpendicular to a substrate plane defined by the substrate, wherein the ribbon beam impacts a substrate over an ion angular distribution about the third axis.

20. The method of claim 18, wherein the scanner comprises a first scan plate and a second scan plate, the method further comprising:
applying a first waveform to the first scan plate; and
applying a second waveform to the second scan plate, wherein the first and second waveform generate the deflecting field as an oscillating deflecting field parallel to the second axis.
